(19) United States
(12) Patent Application Publication
(10) Pub. No.: US 2020/0274047 A1
(43) Pub. Date: Aug. 27, 2020

(54) THERMOELECTRIC FABRIC

(71) Applicant: Mahle International GmbH, Stuttgart (DE)

(72) Inventors: Juergen Gruenwald, Ludwigsburg (DE); Stefan Hoppe, Dorsten (DE)

(21) Appl. No.: 16/646,514

(22) PCT Filed: Aug. 30, 2018
(86) PCT No.: PCT/EP2018/073356

§ 371 Date: Mar. 11, 2020

(30) Foreign Application Priority Data
Sep. 12, 2017 (DE) 10 2017 216 057.8

(51) Int. Cl. H01L 35/32; H01L 35/02; B60N 2/56; B60N 2/58

(52) U.S. Cl. CPC H01L 35/32; B60N 2/58; B60N 2/5692; H01L 35/02

(57) ABSTRACT

A thermoelectric fabric may include a plurality of first threads and a plurality of electrically insulating second threads. The plurality of first threads may each be defined by a plurality of p-doped thread portions, a plurality of n-doped thread portions, and a plurality of electrically conductive thread portions. The plurality of p-doped thread portions and the plurality of n-doped thread portions may be arranged in an alternating manner. The plurality of electrically conductive thread portions may be arranged between the plurality of n-doped thread portions and the plurality of p-dope thread portions. The plurality of electrically conductive thread portions may be structured as a plurality of broad, flexible, stretchable conductive track portions

### CROSS-REFERENCE TO RELATED APPLICATIONS

This application claims priority to International Patent Application No. PCT/EP2018/073356, filed on Aug. 30, 2018, and German Patent Application No. DE 10 2017 216 057.8, filed on Sep. 12, 2107, the contents of both of which are hereby incorporated by reference in their entireties.

### TECHNICAL FIELD

The invention relates to a thermoelectric fabric which can be employed for example for temperature-controlling surfaces in a motor vehicle interior and of motor vehicle seats. Further, a corresponding air conditioning system is described.

### BACKGROUND

From DE 10 2015 217 754 A1 a thermoelectric device is known, with which surfaces in a motor vehicle, in particular a motor vehicle seat in a motor vehicle, can be cooled in order to rapidly cool the motor vehicle seat for increased comfort for example in the case of intense solar irradiation. There, the device comprises a first plurality of threads which serve for example as weft threads, which are equipped with p-doped and n-doped thread portions. When an electric current is conducted through this first plurality of threads, a cooling occurs on the cold sides of the P/N semiconductors because of the Peltier effect and the motor vehicle seat or its seat surface or any other surface in the motor vehicle is cooled. Between the p-doped and n-doped thread portions, undoped conductive track portions for example in the form of copper or aluminium wires are arranged. Furthermore, a second plurality of electrically insulating threads is provided, which serve as weft threads in the fabric. Although aluminium has a lower heat conductivity compared with copper it is however substantially more economical in procurement and is also already used as cooler material in other sectors and is therefore known regarding its characteristics. The thermoelectric device or the fabric is formed and arranged in such a manner that the surface in the motor vehicle, in particular of the motor vehicle seat, is cooled. Warp- and weft threads can each be designed also for the other function.

Starting out from this prior art, the person skilled with the art faces the object of improving such a thermoelectric fabric so that the efficiency is increased.

### SUMMARY

According to the invention, this problem is solved through the subject matter of the independent claim(s). Advantageous embodiments are subject of the dependent claim(s). Furthermore, a corresponding air conditioning system is stated.

The present invention is based on the general idea that instead of the undoped thread portions between the p- and n-doped thread portions broad, flexible, stretchable conductor track portions are now provided, which form the bridges between the thermoelectric semiconductors. These conductive track portions in their entirety form a large surface and thereby optimise the heat transfer to the surface to be temperature controlled.

The p or n-doped thread portions are formed by semiconductor materials in the manner known per se. These materials contain for example bismuth, tellurium and antimony as elementary constituents, a known chemical compound in the thermoelectrically semiconductor material is bismuth-tellurium. These doped thread portions are now connected to broad, flexible, stretchable conductive track portions.

It is evident that through the arrangement of the p- and n-doped thread portions and the direction of the current flow through the thermoelectric fabric a so-called hot side and a so-called cold side are present. Thus, with correct installation position, a surface for example in an interior of the motor vehicle is cooled and the heat being generated passed on to the material arranged under it. This can be for example a motor vehicle seat in order to impart a user of the motor vehicle a pleasant cool seating sensation as quickly as possible after the thermoelectric fabric has been switched on.

The advantage of the invention consists in that through the large-area formation of the conductive track portions between the p- and n-doped thread portions an enlarged surface for the heat transfer or for the cooling or dissipating of heat is available. Thus, a rapid cooling for example of a seating surface is made possible.

In an advantageous further development of the solution according to the invention, the conductive track portions between the doped thread portions comprise an electrically insulating substrate material, in particular polyurethane (PU) or polyimide, in order to have an adequate mechanical stability with flexibility for example for adapting to different shapes still being present. Here, the conductive track portions are substantially completely surrounded by the substrate material.

A further advantages configuration of the solution according to the invention provides that the conductive track portions between the doped thread portions consist of copper or aluminium which has a high electrical conductivity and a good heat transfer capacity. For example, the conductive track portion can be formed by a copper wire or aluminium wire following a meander-like course, which is cast into the substrate material such as polyurethane or polyimide. This also allows a stretchability or flexibility of the conductive track portion.

A further configuration of the invention consists in that the conductive track portions are laminated. To this end, a conductive track preferentially of copper or aluminium is laminated onto a first layer of the substrate material and then covered or embedded with a second layer of the substrate material which is preferentially laminated. Basically, these conductive track portions can also be embodied as pure copper strip or aluminium strip. This makes possible a more cost-effective production since the laminating operation is no longer required and such a pure copper strip or aluminium strip has a higher thermal performance cross section based on the entire cross section of the strip, since the strip precisely serves entirely for the heat conduction. Although it is hardly stretchable during normal usage and would trigger major loads under tensile stress, the thermal conductivity however is substantially increased.

According to a further preferred embodiment of the invention, the undoped conductive track portions and the p- and n-doped thread portions are soft soldered to one another. This means that between the various materials or components of the thermoelectric fabric there is a soft solder connection. As a function of the materials, these soft soldered points each consist of a suitable solder and make possible a certain movability of the entire fabric in order to adapt to different surface contours.

According to an advantageous further development of the invention the electrically insulating second threads consist of substrate lamellae which are formed in particular from a closed-pore silicone foam. These substrate lamellae can be produced with the desired elasticity and electrical insulation capacity in order to be woven into a fabric with the first plurality of threads of p- and n-doped thread portions and conductive track portions arranged in-between. Alternatively, the use of foam rubber or similar plastic materials is also possible for the plurality of second threads, wherein materials are preferred which are poorly heat-conductive and yet offer a pleasant feel. Because of the poor thermal conductivity, the hot side and the cold side of the thermoelectric fabric are thermally insulated from one another and the efficiency increased.

According to a further advantageous further development of the invention, undoped conductive track portions between the doped thread portions or conductive track portions are embodied broader than these. Thus, for example with those undoped conductive track portions which are on the top side on the thermoelectric fabric or the weft threads or substrate lamellae are substantially covered. Thus, the effective surface area for the heat transfer or dissipation is increased.

Such a thermoelectric fabric can form the constituent of an air conditioning system in particular for the interior of a motor vehicle. For example, the fabric can be installed under a cover layer in an instrument panel or a lateral trim or any other surface in the interior of the motor vehicle. The thermoelectric fabric is activated either automatically when a conventional air conditioning system is switched on or manually actuated and cools the relevant surface. An actuation can also be performed in an automated manner by way of a total system consideration of the thermal passenger comfort based on sensor data. In particular, the thermoelectric fabric can be installed in a motor vehicle seat in order to rapidly cool the actual seating surface. Because of the conductive tracks following for example a meander-like course and the soft solder points, the fabric can adapt to different shapes of the motor vehicle seat which are brought about among other things through different weights of the motor vehicle occupants.

It is to be understood that the thermoelectric fabric is equipped with electrical supply and discharge lines, a fuse against overvoltage and possibly a temperature sensor for the automatic deactivation in the case that a limit temperature is exceeded or undershot.

In principle, such a thermoelectric fabric can also be employed in all other technical fields for example for the current generation in flexible surfaces.

Further important features and advantages of the invention are obtained from the subclaims, from the drawings and from the associated figure description by way of the drawings.

It is to be understood that the features mentioned above and still to be explained in the following cannot only be used in the respective combination stated but also in other combinations or by themselves without leaving the scope of the present invention.

Preferred exemplary embodiments of the invention are shown in the drawings and are explained in more detail in the following description, wherein same reference numbers relate to same or similar or functionally same components.

### BRIEF DESCRIPTION OF THE DRAWINGS

There it shows, in each case schematically

FIG. 1 shows a thermoelectric fabric in a perspective representation,

FIG. 2 shows a thermoelectric fabric in plan view,

FIG. 3 shows a thermoelectric fabric in the cross section along the line A-A from FIG. 1 and

FIG. 4 shows a thermoelectric fabric in the cross section along the line B-B from FIG. 1.

### DETAILED DESCRIPTION

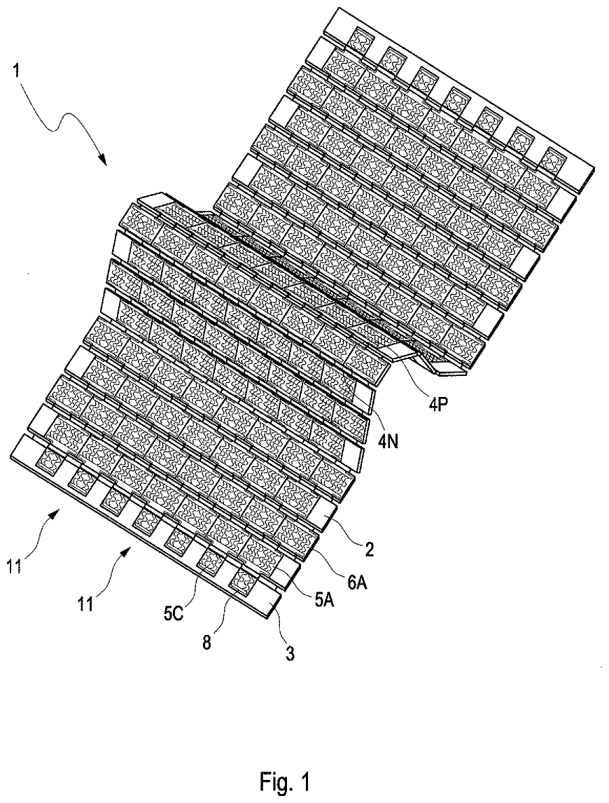

According to FIG. 1, a thermoelectric fabric 1 according to the invention comprises weft threads 2, which preferentially consist of a closed-cell silicone foam and are formed so as to be electrically insulating, and warp threads 11, which in turn are composed of multiple components.

The warp threads 11 consist among other things of conductive track portions 5A, 5B, 6A, 6B which are formed for example through copper wires 10 or aluminium wires which are arranged meander-like. Between the conductive track portions 5A, 5B, 6A, 6B a semiconductor element or a doped conductive track portion 4n, which is n-doped and a semiconductor element or a doped conductive track portion 4p, which is p-doped is arranged in each case. The conductive track portions 4n and 4p are n- or p-doped and contain the relevant semiconductor material, for example bismuth-telluride and antimony-telluride. However all other materials known to the person skilled in the art are conceivable.

The semiconductor portions 5A, 5B, 6A, 6B and conductive track portions 4n, 4p are each connected with soft solder points 7 which make possible an adequate flexibility of the thermoelectric fabric 1. In principle, connecting the different conductive track portions 5A, 5B, 6A, 6B as well as 4n, 4p is also possible by means of wires, elastic conductors or the like. Each of the conductive track portions 5A, 5B and 6A, 6B are alternatively intertwined with the weft threads 2 or the closed-cell silicone foam in order to form the thermoelectric fabric 1.

Because of the meander-like arrangement of the copper wire 10 or of the aluminium wire, the conductive track portions 5A, 5B, 6A, 6B are flexible and can change for example their longitudinal extension so as not to be damaged among other things in a seat cushion of a motor vehicle seat. Thus a stretch region is formed. The conductive track portions 5A, 5B, 6A, 6B and the doped conductive track portions 4n, 4p are preferentially applied to a substrate. The warp threads 11 or the conductive track portions 5A, 5B, 6A, 6B are provided with termination lamellae 3 on both ends, in order to make possible an electrical contacting to an external current supply for example from an electrical system of a motor vehicle. As part of the warp threads 11, conductive track portions 5C, 6C, which interact with an electrical contact surface 8, are arranged on the termination lamella 3.

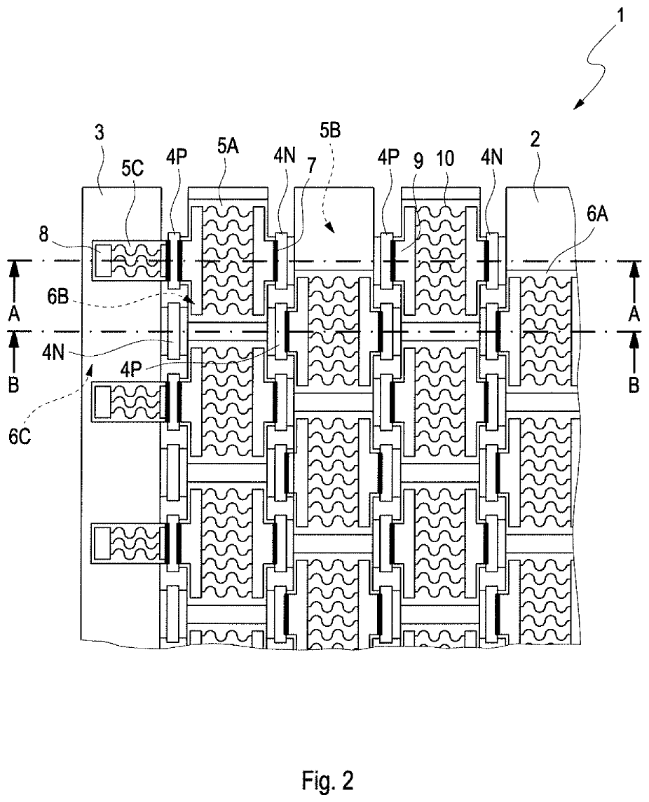

From the plan view in FIG. 2 the large effective surface of the conductive track portions 5A, 5B, 6A, 6B is evident, wherein these are embodied in particular broader than the doped conductive track portions 4n, 4p. The conductive track portions 5A, 5B, 6A, 6B comprise edge-side connecting regions 9 which via soft soldered points 7 are connected to the doped conductive track portions 4n, 4p.

From FIG. 2 it is evident, furthermore, that the undoped conductive track portions 5A, 5B, 6A, 6B are broader for example than the conductive track portions 5C on the termination lamellae 3, in order to obtain as full an area coverage of the thermoelectric fabric 1 as possible.

The sweeping arrows serve to indicate that on the underside of the termination lamellae 3 a conductive track portions 6C for the electrical contacting and on the underside of the weft thread 2 a conductive track portion 6B are arranged.

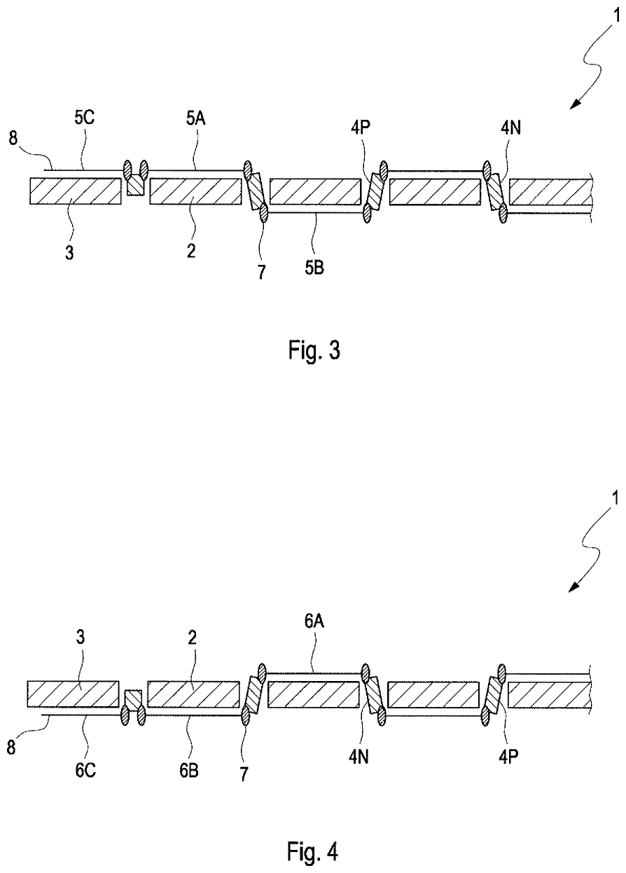

From the cross-sectional representations in FIGS. 3 and 4 it is evident that for example the conductive track portions 5A, 6A are arranged on the top side of the thermoelectric fabric 1 and the conductive track portions 5B, 6B on the underside. With suitable current flow through the doped conductive track portions 4n, 4p, the top side of the thermoelectric fabric 1 can thus serve for example as cold side for dissipating excess heat of a heated surface and the underside as hot side which dissipates the heat to a material located there under.

1. A thermoelectric fabric, comprising:
a plurality of first threads each defined by a plurality of p-doped thread portions, a plurality of n-doped thread portions, and a plurality of electrically conductive thread portions, the plurality of p-doped thread portions and the plurality of n-doped thread portions arranged in an alternating manner, the plurality of electrically conductive thread portions arranged between the plurality of n-doped thread portions and the plurality of p-dope thread portions;
a plurality of electrically insulating second threads; and
wherein the plurality of electrically conductive thread portions are structured as a plurality of broad, flexible, stretchable conductive track portions.

2. The thermoelectric fabric according to claim 1, wherein the plurality of conductive track portions include a substrate material.

3. The thermoelectric fabric according to claim 1, wherein the plurality of conductive track portions are composed of a metal.

4. The thermoelectric fabric according to claim 1, wherein the plurality of conductive track portions are laminated.

5. The thermoelectric fabric according to claim 1, wherein the plurality of p-doped thread portions and the plurality of n-doped thread portions are connected to the plurality of conductive track portions via a soft-soldered connection.

6. The thermoelectric fabric according to claim 1, wherein the plurality of electrically insulating second threads are each structured as a substrate lamellae.

7. The thermoelectric fabric according to claim 1, wherein the plurality of conductive track portions substantially cover the thermoelectric fabric completely.

8. An air conditioning system for a motor vehicle, comprising the thermoelectric fabric according to claim 1.

9. The thermoelectric fabric according to claim 1, wherein:
the plurality of first threads and the plurality of electrically insulating second threads are woven together such that the plurality of first threads are arranged as warp threads and the plurality of electrically insulating second threads are arranged as weft threads;
the warp threads extend parallel to each other;
the weft threads extend parallel to each other and transversely to the warp threads; and
the warp threads alternately extend over and under the weft threads.

10. The thermoelectric fabric according to claim 9, further comprising a first termination lamellae and a second termination lamellae extending parallel to one other and to the plurality of electrically insulating second threads, wherein:
a first end of each of the plurality of first threads is connected to the first termination lamellae;
a second end of each of the plurality of first threads is connected to the second termination lamellae; and
the plurality of electrically insulating second threads are disposed between the first termination lamellae and the second termination lamellae.

11. The thermoelectric fabric according to claim 1, wherein:
the plurality of electrically insulating second threads extend parallel to one another; and
the plurality of electrically insulating second threads are each arranged between and directly adjacent to a respective p-doped thread portion of the plurality of p-doped thread portions and a respective n-doped thread portion of the plurality of n-doped thread portions.

12. The thermoelectric fabric according to claim 1, further comprising at least two termination lamellae, wherein the plurality of first threads are connected to and extend between the at least two termination lamellae.

13. The thermoelectric fabric according to claim 1, wherein at least one of the plurality of conductive track portions is structured as a pure copper strip.

14. The thermoelectric fabric according to claim 1, wherein at least one of the plurality of conductive track portions is structured as a pure aluminium strip.

15. The thermoelectric fabric according to claim 1, wherein the plurality of electrically insulating second threads are composed of a closed-pore silicone foam.

16. The thermoelectric fabric according to claim 2, wherein the substrate material is polyurethane.

17. The thermoelectric fabric according to claim 2, wherein the substrate material is polyamide.

18. A thermoelectric fabric, comprising:
a plurality of first threads each defined by a plurality of p-doped thread portions, a plurality of n-doped thread portions, and a plurality of electrically conductive thread portions;
a plurality of electrically insulating second threads;
the plurality of p-doped thread portions and the plurality of n-doped thread portions arranged in an alternating manner and connected to one another via the plurality of electrically conductive thread portions;
each of the plurality of p-doped thread portions and each of the plurality of n-doped thread portions arranged between two electrically conductive thread portions of the plurality of electrically conductive thread portions;
wherein the plurality of electrically conductive thread portions are structured as a plurality of broad, flexible, stretchable conductive track portions; and
wherein the plurality of first threads and the plurality of second threads are woven together such that the plurality of first threads are arranged as warp threads and the plurality of second threads are arranged as weft threads.

19. The thermoelectric fabric according to claim 18, wherein:
the plurality of first threads extend parallel to each other;
the plurality of second threads extend parallel to each other and transversely to the plurality of first threads;
the plurality of second threads are each arranged between and directly adjacent to a respective p-doped thread portion of the plurality of p-doped thread portions and a respective n-doped thread portion of the plurality of n-doped thread portions; and
the plurality of electrically conductive thread portions alternately extend over and under the plurality of second threads.

20. The thermoelectric fabric according to claim 19, wherein:
the plurality of second threads extend parallel to one another in a first direction;
the plurality of second threads each have an elongated cross-sectional profile lying perpendicular to the first direction; and
the plurality of second threads are arranged such that an elongated extent of the cross-sectional profile of each of the plurality of second threads extends between the respective p-doped thread portion and the respective n-doped thread portion.
